(19) United States
(12) Patent Application Publication
(10) Pub. No.: US 2009/0108264 A1
(43) Pub. Date: Apr. 30, 2009

(54) LAMINATED CONDUCTIVE FILM, ELECTRO-OPTICAL DISPLAY DEVICE AND PRODUCTION METHOD OF SAME

(75) Inventors: Kazunori Inoue, Tokyo (JP); Masami Hayashi, Tokyo (JP); Nobuaki Ishiga, Kumamoto (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 12/262,612

(22) Filed: Oct. 31, 2008

(30) Foreign Application Priority Data
Oct. 31, 2007 (JP) 2007-282687

(51) Int. Cl. H01L 21/77; H01L 27/088; C23C 16/513; B32B 15/04; B32B 9/00; C23C 14/34; H01B 13/06

(52) U.S. Cl. 257/59; 438/29; 427/535; 204/192.15; 428/457; 428/698; 428/702; 257/E21.598; 257/E27.06

(57) ABSTRACT

The present invention provides a laminated conductive film, comprising a transparent conductive film and Al-based film, that is capable of realizing a high-quality film with superior electro-optical properties, without providing a buffer layer or protective layer. A laminated conductive film according to one aspect of the present invention is provided with a transparent conductive film having optical transmissivity, and a metal conductive film laminated directly on the transparent conductive film and electrically connected to the transparent conductive film. The metal conductive film is made of Al or has Al as a main component thereof and contains at least one of nitrogen atom and oxygen atom at least in the vicinity of the interface with the transparent conductive film.

### BACKGROUND OF THE INVENTION

1. Field of the Invention

The present invention relates to a laminated conductive film having a transparent conductive film and to a production method thereof. In addition, the present invention relates to an electro-optical display device having a thin film transistor (TFT) and a pixel electrode, and to a production method thereof.

2. Description of Related Art

Electro-optical display devices, as exemplified by liquid crystal display devices and electroluminescence (EL) display devices, have the characteristics of a thin shape and low power consumption. Electro-optical display devices are widely used in applications such as the displays of cellular telephones, electronic assistants and other portable information devices, monitors of personal computer, image monitors of digital cameras and video cameras and, more recently, space-saving, large-screen TVs by taking advantage of these characteristics.

Among these electro-optical display devices, liquid crystal display devices using liquid crystals for the electro-optical elements differ from EL display devices and cathode ray tubes (CRT) in that they do not emit light spontaneously. Consequently, an illumination device comprised of a fluorescent tube and the like and referred to as backlight is arranged on the back or to the side of a liquid crystal display panel. Images are displayed by controlling the amount of light transmitted from this backlight with a liquid crystal layer. Devices using this type of so-called transmissive liquid crystal display panel are typically used in liquid crystal display devices. However, this type of transmissive liquid crystal display panel made it difficult to recognize the display as a result of the display light of the display panel appearing darker than the surrounding light when used outdoors during the day when surrounding light is extremely bright.

Therefore, some portable information devices, for which there are numerous opportunities for being used outdoors or while carrying, use a reflective liquid crystal display device, which differs from transmissive liquid crystal display devices in that a reflecting plate is installed in the display unit of the display panel, and a display is generated by reflecting surrounding light with the surface of the reflecting plate instead of using light from a backlight. Reflective liquid crystal display devices using reflected surrounding light conversely have the shortcoming of a significant reduction in visibility in cases of low levels of surrounding light.

In order to resolve the respective problems of transmissive and reflective liquid crystal display devices as described above, a semi-transmissive liquid crystal display device, having a configuration that realizes both a transmissive display and a reflective display with a single liquid crystal display panel by forming a reflective-transmissive type, or so-called semi-transmissive type, of pixel electrode that transmits a portion of backlight while also reflecting a portion of the surrounding light, is disclosed in, for example, FIGS. 1 and 2 of Japanese Unexamined Patent Application Publication NO. 11-101992.

Differing from transmissive and reflective types of the related art, this type of semi-transmissive liquid crystal display device requires the formation of both a pixel electrode for light transmission (transmissive electrode) and a pixel electrode for light reflection (reflective electrode). Consequently, it has the shortcomings of causing an increase in the number of production steps and a decrease in production efficiency.

A production method of a semi-transmissive liquid crystal display device for reducing the number of production steps of the transmissive electrode and reflective electrode is disclosed in, for example, FIGS. 1 and 2 of Japanese Unexamined Patent Application Publication NO. 2005-215277 (Kawasaki et al.). According to this production method, a transmissive electrode and reflective electrode are formed in a single photolithography process, without increasing the number of photolithography processes, by using a photosensitive resin (photo-resist) pattern formed by halftone exposure after sequentially and consecutively depositing, for example, a transparent conductive layer made of ITO, a buffer layer made of molybdenum (Mo) and a highly reflective metal layer made of aluminum (Al) for use as a pixel electrode.

However, in the production method as described above as well, not only was it difficult to form a structure in which Al and ITO are laminated directly, but as is also described in Japanese Unexamined Patent Application Publication NO. 11-281993 (Sawayama et al.) and Japanese Unexamined Patent Application Publication NO. 2003-50389 (Sakamoto et al.), it was necessary to laminate a buffer layer made of Mo and the like between the Al and ITO. There are two possible reasons for this as is also disclosed in the publications by Kawasaki et al., Sawayama et al. or Sakamoto et al.

(1) In the case pinholes or defects are present in a portion of the Al film, during development by an organic alkaline developing solution used when patterning the photoresist of the Al/ITO laminated film, a battery reaction occurs at the location of the defect that uses the Al and ITO as electrodes. As a result, oxidative corrosion of the Al and reductive corrosion of the ITO occur. Consequently, display defects occur caused by film separation and deterioration of the transmittance of the transmissive electrode in the form of the ITO film. In order to solve this problem, the battery reaction is prevented by interposing a buffer layer made of Mo between the Al film and ITO film.

(2) When an Al film is deposited directly onto an ITO film, the Al reacts with the oxygen of the ITO at the interface thereof resulting in the formation of insulating aluminum oxide (AlOₓ) reactive layer. Consequently, electrical continuity between the Al and ITO is impaired. Electrical signals between the transmissive electrode and reflective electrode are interrupted resulting in a defective display. In order to solve this problem, impairment of electrical continuity is prevented by interposing a Mo buffer layer between the Al and ITO.

Furthermore, the buffer layer is not limited to Mo, but rather chromium (Cr), titanium (Ti), tantalum (Ta) or tungsten (W), for example, can also be used for the buffer layer since it is capable of preventing a battery reaction and impairment of electrical continuity between Al and ITO as described above.

As has been described above, even if the production method disclosed in the publication of Kawasaki et al. is used, although the number of photolithography processes can be reduced, since it is necessary to form an additional metal layer besides the Al and ITO, this method has the shortcoming of causing an increase in the number of deposition steps.

A method for resolving the problems described in (2) above is disclosed in, for example, Japanese Unexamined Patent Application Publication NO. 2003-89864 and Japanese Unexamined Patent Application Publication NO. 2004-214606. According to these publications, the use of an Al-based alloy film, in which nickel (Ni), for example, is added to Al, makes it possible to achieve electrical continuity directly with a transparent conductive film (such as ITO). Moreover, a technology has been disclosed capable of inhibiting a battery reaction between Al and ITO by allowing the spontaneous potential in 3.5% aqueous sodium chloride solution to approach that of ITO.

Furthermore, as a result of studies conducted by the inventors of the present invention, the use of these Al-based alloy films was confirmed to be able to inhibit a battery reaction with ITO, which is the problem described in (1) above, even inorganic alkaline developing solutions comprised of 3.8% tetramethyl ammonium hydroxide (TMAH) conventionally known as a photoresist developing solution.

However, when the inventors of the present invention deposited an AlNi-based alloy directly on an ITO (90% by weight indium oxide+10% by weight tin oxide) film, a large number of film defects in the shape of round spots were determined to occur when viewed with a light microscope. At the locations of these round spot-shaped defects, the film was damaged by metal In and metal Sn reduced on the ITO film below resulting in partial separation of the film. This is thought to be the result of the indium oxide and tin oxide on the surface of the ITO having been partially reduced prior to deposition of the AlNi-based alloy film on the ITO film. Namely, although electrical continuity at the interface between the AlNi and ITO is improved due to the presence of metal In and metal Sn reduced near the interface, spot-shaped defects are thought to have occurred due to this phenomenon. In the case of using a laminated conductive film comprising the deposition of an AlNi-based alloy film on an ITO film as a pixel electrode of a display, these spot-shaped defects become a fatal problem since they lead directly to a defective display. Reliability is also thought to decrease even in the case of using for an electrode film or wiring film.

On the other hand, a technology for improving resistance to reductive plasma by forming a protective film in the form of a ZnO-based transparent conductive film having superior resistance to reduction on an ITO film is disclosed in, for example, Japanese Unexamined Patent Application Publication NO. 6-338223. The use of this technology is presumed to facilitate inhibition of the occurrence of the spot-shaped defects as described above. However, in this case as well, since it is necessary to form an additional ZnO-based transparent conductive film, this technology also had the shortcoming of increasing the number of deposition steps.

Methods using a ZnO-based film for the transparent conductive film instead of an ITO film have also been considered. However, ZnO-based films have inferior optical transmittance and specific resistance as compared with ITO films. For example, in contrast to the transmittance of light having a wavelength of 550 nm being about 95% in the case of ITO films, transmittance in the case of ZnO-based films is 85 to 90%. In addition, in contrast to the specific resistance of ITO films being about 200 μΩ·cm, that of ZnO-based films is 300 to 1000 μΩcm. Consequently, display properties are inferior in the case of using a ZnO-based film for a pixel electrode. Moreover, since ZnO-based films are violently corroded and etched by typically known etching solutions of Al-based metals in the form of phosphoric acid, nitric acid and acetic acid-based chemical solutions, it is extremely difficult to simultaneously carry out wet etching processing on Al-based films and ZnO-based films. Thus, it was substantially impossible to use ZnO-based films as transparent conductive films.

As has been described above, since it is necessary to form a transmissive electrode and reflective electrode for the pixel electrodes in the case of conventionally known semi-transmissive liquid crystal display devices, there were problems in the form of an increase in the number of production steps and decreased production efficiency. In addition, in the case of attempting to form the transmissive electrode and reflective electrode collectively, it is difficult to produce an ITO or other oxide transparent conductive film serving as a transmissive electrode and high reflectance Al-based alloy film serving as a reflective electrode in the form of a directly laminated film using conventionally known production methods, and since it was necessary to form an additional metal buffer layer between the Al and ITO, this resulted in the problems of an increase in the number of deposition steps and decreased production efficiency.

### SUMMARY OF THE INVENTION

With the foregoing in view, an object of the present invention is to provide a laminated conductive film comprising a transparent conductive film and Al-based film, that is capable of realizing a high-quality film with superior electro-optical properties, without providing a buffer layer or protective layer.

According to an aspect of the present invention, there is provided a laminated conductive film including: a transparent conductive film having optical transmissivity; and a metal conductive film laminated directly on the transparent conductive film and electrically connected to the transparent conductive film. In the laminated conductive film, the metal conductive film is made of Al or has Al as a main component thereof, and contains at least one of nitrogen atom and oxygen atom at least in the vicinity of an interface with the transparent conductive film.

According to another aspect of the present invention, there is provided an electro-optical display device including: a plurality of gate wiring formed on a substrate; a plurality of source wiring arranged so as to intersect with the gate wiring with a first insulating film interposed therebetween; a plurality of thin film transistors formed in the vicinity of intersecting sections of the gate wiring and the source wiring; and pixel electrodes connected to the thin film transistors and provided in regions surrounded by the gate wiring and the source wiring. In the electro-optical display device, the pixel electrodes are provided with a transmissive region comprising a transparent conductive film, and a reflective region comprising a metal conductive film having Al as a main component thereof, laminated directly on the transparent conductive film and electrically connected to the transparent conductive film. Furthermore the metal conductive film is made of Al or has Al as a main component thereof, and contains at least one of nitrogen atom and oxygen atom at least in the vicinity of an interface with the transparent conductive film.

According to another aspect of the present invention, there is provided a production method of a laminated conductive film, including the steps of: forming a transparent conductive film on a substrate; and forming a metal conductive film directly on the transparent conductive film. The metal conductive film being made of Al or having Al as a main component thereof and containing at least one of nitrogen atom and oxygen atom at least in the vicinity of an interface with the transparent conductive film.

According to another aspect of the present invention, there is provided a production method of an electro-optical display device which includes, on a substrate, a plurality of gate wiring, a plurality of source wiring substantially orthogonal to the gate wiring with a first insulating film interposed therebetween, a plurality of thin film transistors formed in the vicinity of intersecting sections of the gate wiring and the source wiring, and pixel electrodes connected to the thin film transistors and provided in regions surrounded by the gate wiring and the source wiring, including the steps of: forming a transmissive region of the pixel electrodes comprising a transparent conductive film, and forming a reflective region of the pixel electrodes by laminating, directly on the transparent conductive film, a metal conductive film made of Al or having Al as a main component thereof and containing at least one of nitrogen atom and oxygen atom at least in the vicinity of an interface with the transparent conductive film.

According to the present invention, a laminated conductive film comprising a transparent conductive film and Al-based film can be provided that is capable of realizing a high-quality film with superior electro-optical properties, without providing a buffer layer or protective layer. In addition, a method of producing the above-mentioned laminated conductive film can also be provided. Moreover, an electro-optical display device that uses this laminated conductive film, and a production method thereof, can also be provided.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is an overhead view showing the configuration of a semi-transmissive liquid crystal display device according to a first embodiment of the present invention;

FIG. 2 is a cross-sectional view showing the configuration of a semi-transmissive liquid crystal display device according to a first embodiment;

FIG. 3 is an overhead view showing the configuration of a TFT active matrix substrate used in a liquid crystal display device according to a first embodiment;

FIG. 4 is a cross-sectional view taken along line IV-IV in FIG. 3;

FIGS. 5A to 5H are cross-sectional views of a production process for explaining the method of producing a TFT active matrix substrate according to a first embodiment; and

FIG. 6 is a cross-sectional view showing the configuration of a TFT active matrix substrate used in a liquid crystal display device according to a second embodiment.

### DESCRIPTION OF THE PREFERRED EMBODIMENTS

Embodiments to which the present invention is applied are explained hereinafter. Incidentally, it should be understood that other embodiments that are consistent with the gist of the present invention also fall within the scope of the present invention.

The following descriptions and drawings are suitably omitted or simplified for the purpose of clarifying the explanation.

### First Embodiment

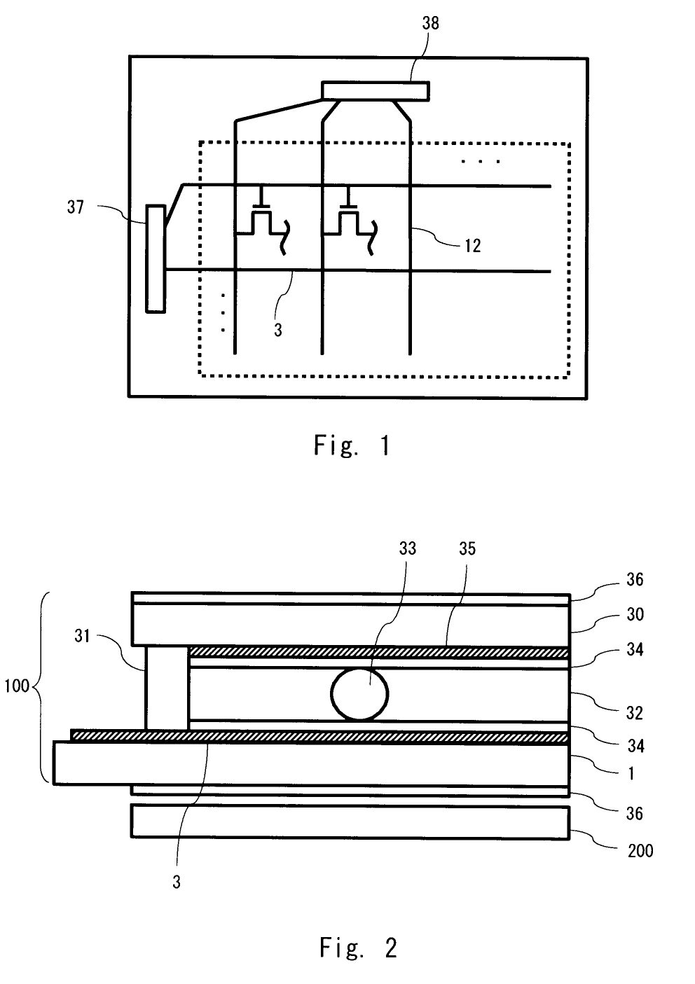

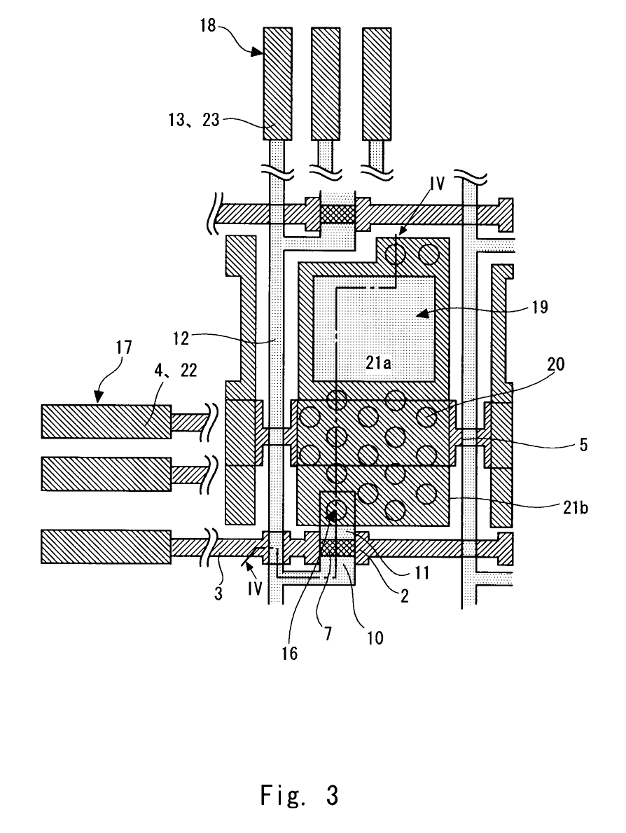

The following provides an explanation of the configuration of a semi-transmissive liquid crystal display device, and production method thereof, as an electro-optical display device according to a first embodiment of the present invention with reference to the drawings. First, with reference to FIGS. 1 and 2, an explanation is provided of the configuration of a semi-transmissive liquid crystal display device according to the present embodiment. FIG. 1 is an overhead view showing the configuration of a semi-transmissive liquid crystal display device according to the present embodiment. In addition, FIG. 2 is a cross-sectional view showing the configuration of a semi-transmissive liquid crystal display device according to the present embodiment.

As shown in FIGS. 1 and 2, a semi-transmissive liquid crystal display according to the present embodiment is provided with a liquid crystal display panel 100 and a backlight 200. The liquid crystal display panel 100 displays images based on input display signals. The backlight 200 is arranged on the non-visualized side of the liquid crystal display panel 100, and radiates light from the back side of the liquid crystal display panel 100. The liquid crystal display panel 100 is provided with an insulating substrate 1, an opposing substrate 30, a sealing material 31, a liquid crystal 32, a spacer 33, gate wiring (scanning lines) 3, source wiring (signal lines) 12, alignment layers 34, a counter electrode 35, optical elements 36, a gate driver 37, a source driver 38 and the like. What should be noted in the present invention is a laminated conductive film formed on the insulating substrate 1, a detailed description of which is provided hereinafter.

As shown in FIG. 1, the insulating substrate 1 is provided with a display section (encircled with a dotted line in FIG. 1) and a peripheral section provided so as to surround the display section. A plurality of gate wiring 3 and a plurality of source wiring 12 are formed in the display section. The plurality of gate wiring 3 is provided in parallel with each other. Similarly, the plurality of source wiring 12 is also provided in parallel with each other. The gate wiring 3 cross the source wiring 12 with a gate insulating film 6 interposed therebetween.

Thin film transistors (TFT) are provided in the vicinity of the intersections of the gate wiring 3 and the source wiring 12. Pixel electrodes (not shown) are formed in regions surrounded by adjacent gate wiring 3 and source wiring 12. Thus, pixels are arranged in the form of a matrix on the insulating substrate 1. The gate of a TFT is connected to the gate wiring 3, the source of the TFT is connected to the source wiring 12, and the drain of the TFT is connected to a pixel electrode. A reflective region and a transmissive region are provided in a single pixel.

In the transmissive region, a pixel electrode comprising a transparent conductive film such as an indium tin oxide (ITO) film is provided on the insulating substrate 1. The transparent conductive film in the transmissive region is formed continuously with the transparent conductive film in the reflective region. In the reflective region, a metal film having high reflectance is formed by laminating onto the transparent conductive film to comprise a pixel electrode. A region in which pluralities of these pixels are formed is a display section.

On the other hand, a color filter (not shown) and the counter electrode 35 are formed on the opposing substrate 30. The entire region in which the color filter is provided is a display section. The counter electrode 35 is actually a transparent electrode formed over substantially the entire surface of the opposing substrate 30 so as to oppose the pixel electrode. The counter electrode 35 is formed by a transparent conductive film of, for example, indium tin oxide (ITO).

The alignment layer 34 is formed on the surface of the insulating substrate 1 that opposes to the opposing substrate 30. Similarly, the alignment layer 34 is formed on the surface of the opposing substrate 30 that opposes to the insulating substrate 1. The space between both substrates is maintained at a predetermined interval by the spacer 33. The peripheries of these substrates are adhered by the sealing material 31, and the liquid crystal 32 is sealed in the space formed by both these substrates and the sealing material 31. The liquid crystal 32 interposed between both these substrates is aligned in a predetermined direction by the alignment layer 34. In addition, the optical elements 36 are respectively placed on the outer surface of the insulating substrate 1 and the opposing substrate 30. A plurality of layered phase difference plates or polarizing plates and the like are arranged for the optical elements 36.

The liquid crystal display panel 100 is driven by the gate driver 37 and the source driver 38, which output various control signals, scanning signals, display signals and the like required for displaying images, based on image data input from the outside. The backlight 200 is provided on the back of the liquid crystal display panel 100. The backlight 200 radiates light onto the liquid crystal display panel 100 from the non-visualized side of the liquid crystal display panel 100. A typical configuration provided with a light source, light guide, reflective sheet and the like can be used for the backlight 200.

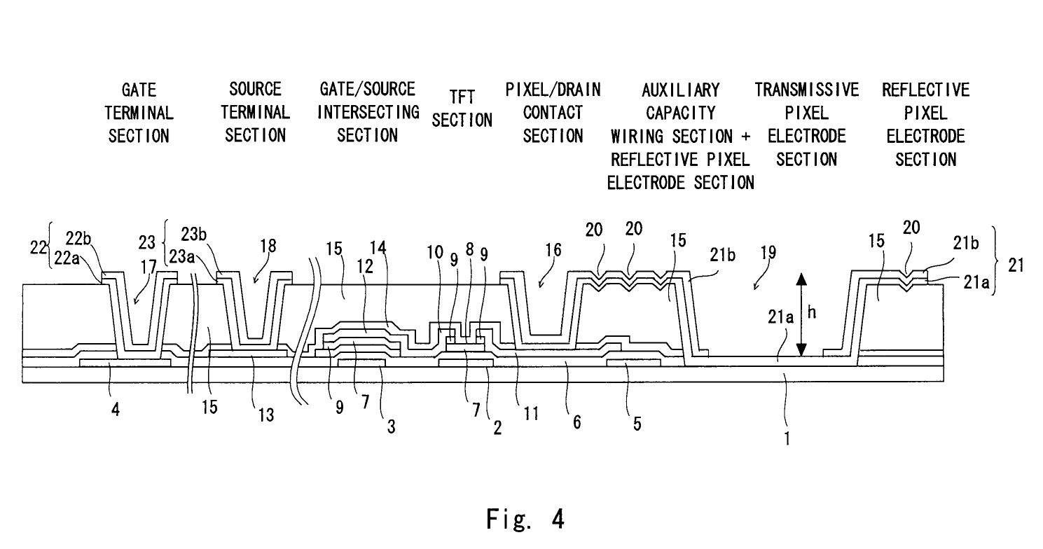

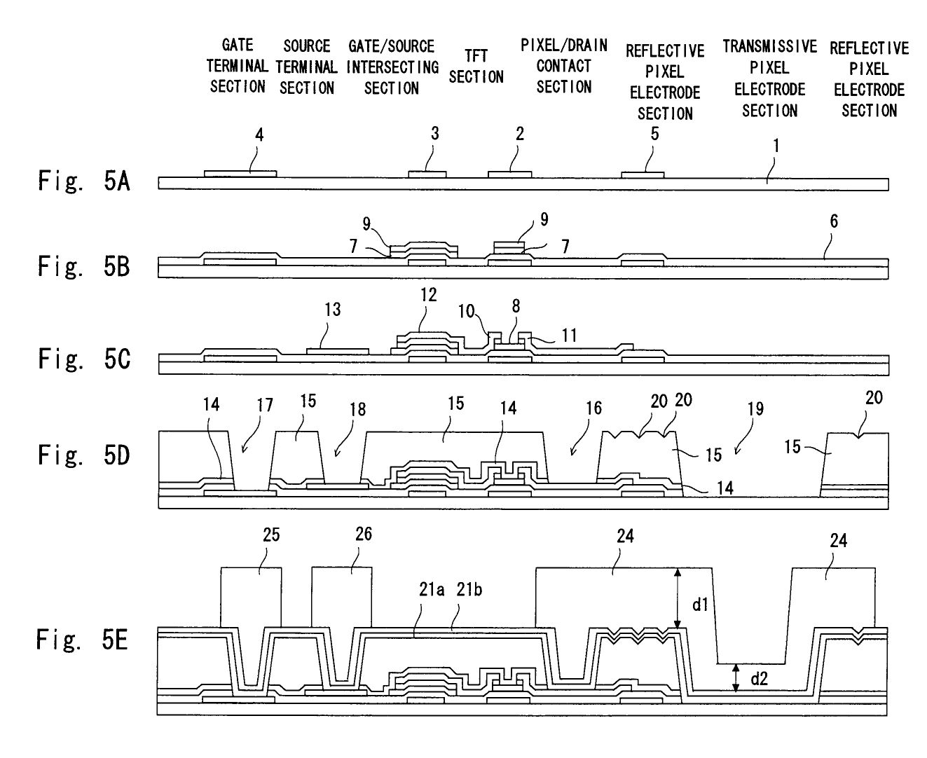

Here, an explanation is provided of the configuration of a TFT active matrix substrate used in a semi-transmissive liquid crystal display device according to the present embodiment with reference to FIGS. 3 and 4. FIG. 3 is an overhead view showing a portion of a display section and an input terminal section of the insulating substrate 1 according to the present embodiment. FIG. 4 is a cross-sectional view taken along line IV-IV of FIG. 3. In addition, a cross-section of a terminal section outside a display region is also shown in FIG. 4. The same reference symbols are used to indicate the same constituent members in FIGS. 3 and 4.

As shown in FIGS. 3 and 4, a gate terminal section, a source terminal section, a TFT section and a pixel section and so forth are formed in the TFT active matrix substrate. A transparent substrate made of glass or plastic and the like can be used for the insulating substrate 1 in order to form a transmissive region that transmits light. At least a gate electrode 2, the gate wiring 3, a gate terminal 4 and an auxiliary capacity electrode 5 are made of a first metal conductive film on the insulating substrate 1, the gate wiring 3, a gate terminal 4 and an auxiliary capacity electrode 5 are at least formed on the insulating substrate 1. The gate wiring 3 extends from the gate electrode 2. The gate terminal 4 is connected to the gate wiring 3, and is provided to input scanning signals output from the gate driver 37.

The gate insulating film 6 is provided on the gate wiring 3, the gate terminal 4 and the auxiliary capacity electrode 5 comprised of a first metallic film. A semiconductor layer 7 is provided on the gate insulating film 6 at the region where the gate electrode 2 is formed. A channel section 8 is formed in this semiconductor layer 7. An ohmic contact layer 9 is formed on a portion of the semiconductor layer 7. A source electrode 10 and a drain electrode 11 are respectively formed on the ohmic contact layer 9. Namely, the source electrode 10 and the drain electrode 11 are respectively electrically connected to the semiconductor layer 7 via the ohmic contact layer 9 to compose a thin film transistor (TFT). The source wiring 12, which is substantially orthogonal to the gate wiring 3, is connected to the source electrode 10. Furthermore, the source wiring 12 is connected to a source terminal 13. The source terminal 13 is provided for input of video signals output from the source driver 38.

A first interlayer insulating film 14 is provided on the source electrode 10, the drain electrode 11 and the source wiring 12. In addition, a second interlayer insulating film 15 is provided on the first interlayer insulating film 14. A pixel drain contact hole 16, a gate terminal section contact hole 17 and a source terminal section contact hole 18 are formed in the first interlayer insulating film 14 and the second interlayer insulating film 15. In addition, an opening 19 is provided in the region serving as a transmissive pixel electrode section of the first interlayer insulating film 14 and the second interlayer insulating film 15. A light scattering section 20 having surface irregularities is at least provided on the surface of the region serving as a reflective pixel electrode section of the second interlayer insulating film 15. The light scattering section 20 scatters reflected light to improve reflective display properties. A pixel electrode 21 is provided on the second interlayer insulating film 15. The pixel electrode 21 contains a lower layer transparent conductive film 21a and an upper layer reflective metal film 21b. The transparent conductive film 21a is electrically connected to the drain electrode 11 via the pixel drain contact hole 16. In the reflective pixel electrode section, the pixel electrode 21 employs a bilayer structure comprising the transparent conductive film 21a for the lower layer and the reflective metal layer 21b for the upper layer. In the transmissive pixel electrode section, the pixel electrode 21 is formed with the transparent conductive film 21a by selectively removing the upper layer reflective metal film.

Thus, in the reflective region, the reflective metal film 21b is formed by laminating directly on the transparent conductive film 21a. In addition, the reflective metal film 21b is made of Al or has Al as a main component thereof, and contains at least one of nitrogen atom and oxygen atom in the vicinity of the interface with the transparent conductive film 21a. Furthermore, impurities unavoidable during the course of production may be contained in the reflective metal film 21b. In this manner, since the reflective metal film contains at least one of nitrogen atom and oxygen atom in the vicinity of the interface with the transparent conductive film, electrical connection between the reflective metal film 21b and the transparent conductive film 21a is favorable. In addition, the occurrence of display defects attributable to reduction of Indium oxide in the transparent conductive film 21a can be prevented. Consequently, production is possible at a favorable yield with high display quality. In addition, a bilayer film, in which a reflective pixel electrode in the form of Al-based film (Al film or an alloy film having Al as a main component thereof) and having high reflectance and a transmissive electrode in the form of an ITO film having high transmittance are laminated directly, can be composed without having to additionally form a buffer layer. Consequently, production efficiency can be improved.

Furthermore, the reflective metal film 21b preferably contains at least one type of atom selected from the group consisting of Fe, Co and Ni of group VIII of the periodic table and C, Si and Ge of group IVb of the periodic table in the vicinity of the interface with the transparent conductive film 21a. As a result, the specific resistance of the reflective metal film 21b can be lowered, thereby resulting in a pixel electrode material having superior heat resistance.

In addition, in the gate terminal section, a gate terminal pad 22 is electrically connected to the gate terminal 4 via the gate terminal section contact hole 17. Similar to the pixel electrode 21 in the reflective pixel electrode section, the gate terminal pad 22 employs a bilayer structure comprised of a lower layer transparent conductive film 22a and an upper layer reflective metal film 22b. In the source terminal section, a gate terminal pad 23 is electrically connected to the source terminal 13 via the source terminal section contact hole 18. Similar to the pixel electrode 21 in the reflective pixel electrode section, the source terminal pad 23 employs a bilayer structure comprised of a lower layer transparent conductive film 23a and an upper layer reflective metal film 23b. Wiring within the pixel drain contact hole 16 and on the light scattering section 20 employs a bilayer structure comprised of the lower layer transparent conductive film 22a and the upper layer reflective metal film 22b.

Thus, the reflective metal film 21b is formed by directly laminating on the transparent conductive film 21a in not only the reflective pixel electrode section but also in the wiring sections and the terminal sections. In addition, the reflective metal film 21b is made of Al or has Al as a main component thereof, and contains at least one of nitrogen atom and oxygen atom in the vicinity of the interface with the transparent conductive film 21a. As a result, the electrical connection between the reflective metal film 21b and the transparent conductive film 21a is favorable. In addition, the occurrence of display defects attributable to reduction of Indium oxide in the transparent conductive film 21a can be prevented.

The TFT active matrix substrate composed in the manner described above and the opposing substrate 30 provided with a color filter for color display, counter electrode and the like are laminated at a fixed interval (cell gap) with the sealing material 31 interposed therebetween. A display panel for a semi-transmissive liquid crystal display device according to the present embodiment can be produced by injecting liquid crystal into the space formed by the TFT active matrix substrate, the opposing substrate and the sealing material and sealing therein.

At this time, height (depth) h of the opening 19 of the transmissive pixel electrode section is preferably set to be about ½ the cell gap of the display panel. As a result, the path length over which light from the periphery is reflected by the reflective pixel electrode section and passes back and forth through the liquid crystal layer, and the path length over which light from the backlight arranged on the back passes through the transmissive pixel electrode and then passes through the liquid crystal layer, can be made to approach each other. More specifically, the optical path length in each of the transmissive pixel electrode section and the reflective pixel electrode section is optimized in consideration of the refractive index and the like of the substance through which the light passes. As a result, the optical properties of the transmissive pixel electrode section and the reflective pixel electrode section can be aligned, thereby allowing the obtaining of high-quality display properties. Although an example of removing the second interlayer insulating layer 15 of the transmissive pixel electrode section has been described in the present embodiment, the interlayer insulating layer 15 may be allowed to remain so as to be thinner than the reflective region in order to optimize the optical path length.

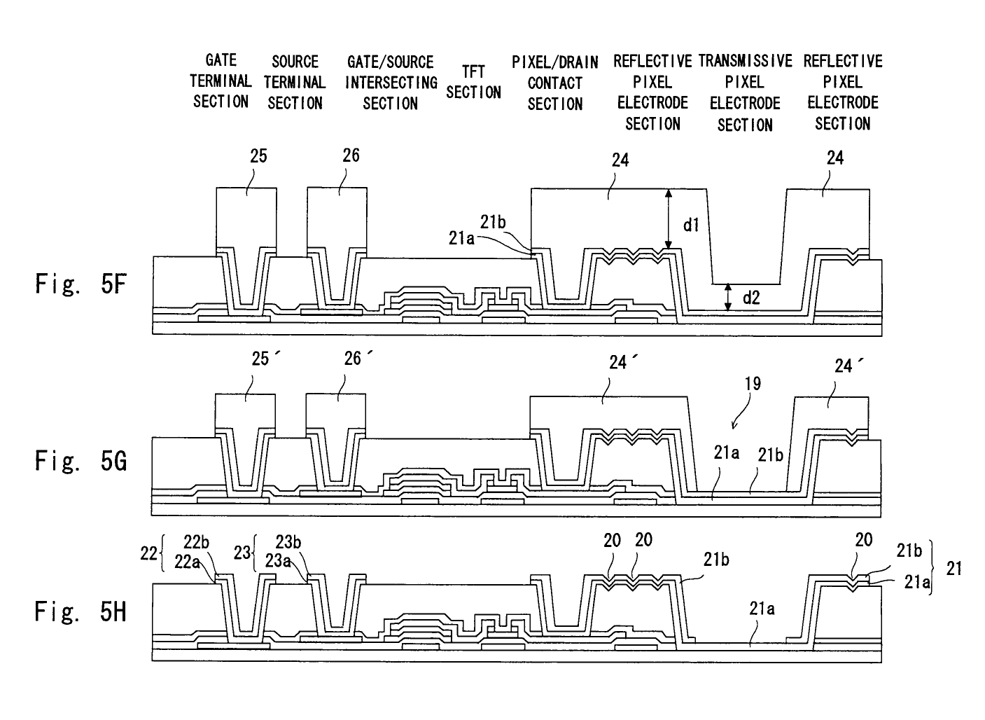

The following provides an explanation of a method of producing the TFT active matrix substrate of the semi-transmissive liquid crystal display device according to the present embodiment with reference to FIGS. 5A to 5H. FIGS. 5A to 5H are cross-sectional views of a production process for explaining the method of producing the TFT active matrix substrate according to the present embodiment.

First, a first metal conductive film is deposited on the transparent insulating substrate 1 in the form of a glass substrate and the like. In a first photolithography process, the gate electrode 2, the gate wiring 3, the gate terminal 4 and the auxiliary capacity electrode 5 are formed as shown in FIG. 5A.

For example, Cr is deposited at a thickness of 200 nm by sputtering using a known Ar gas. Subsequently, a photoresist pattern (not shown) is formed and this is then used as a mask to etch the Cr using a conventionally known chemical solution containing cerium ammonium nitrate and perchloric acid. The photoresist pattern is then removed to obtain the gate electrode 2, the gate wiring 3, the gate terminal 4 and the auxiliary capacity electrode 5.

Next, a first insulating film in the form of the gate insulating film 6 is deposited so as to cover the gate electrode 2, the gate wiring 3, the gate terminal 4 and the auxiliary capacity electrode 5. Films to serve as the semiconductor layer 7 and the ohmic contact layer 9 are then sequentially deposited on the gate insulating film 6. Subsequently, in a second photolithography process, the semiconductor layer 7 and the ohmic contact layer 9 are formed as shown in FIG. 5B. As a result, a semiconductor pattern comprised of the semiconductor layer 7 and the ohmic contact layer 9 is formed in the upper layer of the gate electrode 2. Furthermore, in the present embodiment, the semiconductor pattern comprised of the semiconductor layer 7 and the ohmic contact layer 9 is also formed in a region where the gate wiring 3 and the source wiring 12 formed in the subsequent step intersect. As a result, coverage of step portions in the gate wiring 3 by the semiconductor pattern can be improved. As a result, disconnections of the source wiring 12 formed later at step portions in the gate wiring 3 can be effectively prevented.

In the present embodiment, silicon nitride (SiNₓ; where, x is a positive number) is formed at a thickness of 400 nm for the gate insulating film 6 using, for example, chemical vapor deposition (CVD). Amorphous silicon (a-Si) at a thickness of 150 nm for the semiconductor layer 7 and a phosphorus (P)-doped n-type amorphous silicon film (n+a-Si) at a thickness of 50 nm for the ohmic contact layer 9 are sequentially deposited on the gate insulating film 6. Subsequently, a photoresist pattern (not shown) is formed and this is then used as a mask to carry out etching by dry etching using a conventionally known fluorine-based gas. The photoresist pattern is then removed to obtain the semiconductor layer 7 and the ohmic contact layer 9 of predetermined shapes.

Next, a second metal conductive film is deposited on the ohmic contact layer 9. Then, in a third photolithography process, the source electrode 10, the drain electrode 11, the source wiring 12 and the source terminal 13 are formed as shown in FIG. 5C. Moreover, the TFT channel section 8 is formed.

In the present embodiment, for example, Cr is first formed at a thickness of 200 nm by sputtering using a known Ar gas for the second metal conductive film. Subsequently, a photoresist pattern is formed and this is then used as a mask to etch the Cr using a conventionally known chemical solution containing cerium ammonium nitrate and perchloric acid. The ohmic contact layer 9 on the semiconductor layer 7 to serve as the TFT channel section 8 is then selectively etched by dry etching using a conventionally known gas containing fluorine and chlorine. Subsequently, the photoresist pattern is then removed to obtain the channel section 8, the source electrode 10, the drain electrode 11, the source wiring 12 and the source terminal 13.

Next, after depositing the first interlayer insulating film (second insulating film) 14, the second interlayer insulating film 15 comprising an organic resin film is formed. Then in a fourth photolithography process, the light scattering section 20 having surface irregularities for scattering reflected light is formed in the region serving as the reflective pixel section on the second interlayer insulating film 15 as shown in FIG. 5D. In addition, the pixel drain contact hole 16 penetrating to the surface of the drain electrode 11, the gate terminal section contact hole 17 penetrating to the surface of the gate terminal 4, and source terminal section contact hole 18 penetrating to the surface of the source terminal 13, and the opening 19 in the transmissive pixel section are at least formed in the first interlayer insulating film 14 and the second interlayer insulating film 15.

For example, silicon nitride (SiNₓ; where, x is a positive number) is formed at a thickness of 100 nm for the first interlayer insulating film 14. An acrylic-based photosensitive organic resin film is then coated to a film thickness of about 3.5 μm by spin coating or slit coating for the second interlayer insulating film 15. Subsequently, a first exposure is carried out directly on the acrylic-based photosensitive organic resin film using a photomask for forming each pattern of the contact holes 16, 17 and 18 and the opening 19. Continuing, a second exposure is carried out at, for example, an exposure level equal to 20 to 40% of the first exposure level using a photomask for forming the surface irregularities of the light scattering section 20. Subsequently, development is carried out with a known organic alkaline developing solution containing tetramethyl ammonium hydroxide (TMAH). As a result, the light scattering section 20 having surface irregularities in the reflective pixel section, the opening 19 in the transmissive pixel section, the pixel drain contact hole 16, the gate terminal section contact hole 17 and the source terminal section contact hole 18 are formed.

Furthermore, in the present embodiment, each of the contact holes 16, 17 and 18, the opening 19 of the transmissive pixel section and the light scattering section 20 are formed by carrying out the first exposure and the second exposure at different exposure levels using different photomasks. However, the present embodiment is not limited thereto. A single photomask can also be used that is provided with a pattern for forming the pixel drain contact hole 16, the gate terminal section contact hole 17, the source terminal section contact hole 18 and the opening 19 and a pattern for forming surface irregularities provided with a filter so as to reduce transmittance of the exposure light to 20 to 40%. As a result, each of the contact holes 16, 17 and 18 as well as the opening 19 and the light scattering section 20 may be formed with a single exposure only. In this case, since the number of exposures can be reduced, the treatment time of the photolithography processes can be shortened thereby making it possible to increase production efficiency. Examples of methods able to be used to reduce transmittance of the exposure light include a method in which a filter film or filter layer that reduces the transmittance of exposure light is provided in a photomask, and a method in which light diffraction phenomena are used by dividing the pattern into narrow slits. These methods are commonly known technologies referred to as halftone exposure technology or gray tone exposure technology.

In addition, although the exposure level of surface irregularity pattern was made to be 20 to 40% of the first exposure level in order to form the contact holes, the present embodiment is not limited thereto. By changing the exposure level, the height of the surface irregularities changes, thereby making it possible to change the light scattering properties. Thus, the exposure level can be suitably adjusted according to the device so as to obtain the required scattering properties as desired.

Finally, the pixel electrode 21 is formed. First, a transparent conductive film and a third metal conductive film are formed by sequentially laminating on the second interlayer insulating film 15. Subsequently, a photoresist is coated and in a fifth photolithography process, a pattern 24 for forming a pixel electrode, a pattern 25 for forming a gate electrode pad, and a pattern 26 for forming a source terminal pad are at least formed as shown in FIG. 5E. At this time, a film thickness d2 of the photoresist on the region of the opening 19 of the transmissive pixel electrode section is formed to be less than a film thickness d1 of the photoresist of the reflective pixel electrode section. The photoresist film thickness d2 is preferably ½ or less the film thickness d1.

In the present embodiment, ITO comprised mainly of indium oxide and tin oxide is deposited at a thickness of 100 nm by a known sputtering method for the transparent conductive film. Subsequently, an AlNi film containing nitrogen atoms is deposited at a thickness of 100 nm by sputtering in a mixed gas containing nitrogen (N₂) in Ar gas and using as a target an AlNi alloy in which Ni has been added at 2 at % (atom %) to Al for the third metal conductive film. Here, a DC magnetron sputtering method, for example, is used at a deposition DC power density of 3 W/cm², a flow rate ratio of pure Ar gas to pure N₂ gas of 60:40, and a gas pressure of 0.2 Pa. As a result, an Al-based alloy film is deposited having a composite ratio of Al, 2 at % Ni and 20 at % N. This Al-based alloy film has specific resistance of 50 μΩ and high reflectance of 85% or more for light at a wavelength of 550 nm.

Next, a photoresist is coated to a film thickness of about 3.5 μm by spin coating or slit coating for the resist mask. The pattern 25 for forming the gate terminal pad, the pattern 26 for forming the source terminal pad, and the pattern 24 for forming the pixel electrode, which has different film thicknesses such that the thickness at the reflective pixel electrode section is about 3.5 μm and the thickness at the opening 19 of the transmissive pixel electrode section is about 1.5 μm, are then formed. Photoresist patterns having different film thicknesses in this manner can be formed using the halftone exposure technology or gray tone exposure technology as previously described.

Next, the third metal conductive film and the transparent conductive electrode are etched using the photoresist patterns 24, 25 and 26 as masks. In the present embodiment, the third metal conductive film is first wet-etched using a conventionally known Al etching solution in the form of a chemical solution containing phosphoric acid, nitric acid and acetic acid. Next, the transparent conductive film is continuously wet-etched using a conventionally known chemical solution containing oxalic acid. As a result, the reflective metal film 21b comprised of the third metal conductive film and the transparent conductive film 21a are removed from the regions where the photoresist patterns 24, 25 and 26 are not provided as shown in FIG. 5F.

Next, as shown in FIG. 5G, the photoresist in the region where the film thickness in the opening 19 of the transmissive pixel electrode section was d2 is selectively removed by reducing the overall film thickness of photoresist patterns 24, 25 and 26. As a result, the reflective metal film 21b comprised of the third metal conductive film is exposed in that region. In the present embodiment, photoresist patterns 24′, 25′ and 26′ are formed by reducing the overall film thickness of the photoresist using resist ashing treatment using oxygen plasma.

Next, the third metal conductive film in the opening 19 of the transmissive pixel electrode section is selectively removed by wet etching using a chemical solution containing phosphoric acid, nitric acid and acetic acid, with the use of photoresist patterns 24′, 25′ and 26′ as masks. This results in exposure of the transparent conductive film 21a. Subsequently, photoresist patterns 24′, 25′ and 26′ are removed. As a result, the pixel electrode 21, in which the transparent conductive film 21a and the reflective metal film 21b comprised of the third metal conductive film are laminated, the gate terminal pad 22, in which the transparent conductive film 22a and the reflective metal film 22b comprised of the third metal conductive film are laminated, and the source terminal pad 23, in which the transparent conductive film 23a and the reflective metal film 23b comprised of the third metal conductive film are laminated, are formed as shown in FIG. 5H. This completes the TFT active matrix substrate for the semi-transmissive liquid crystal display device according to the first embodiment.

Moreover, this TFT active matrix substrate and the opposing substrate 30 provided with a color filter for color display, counter electrode and the like are laminated at a fixed interval (cell gap) using the sealing material. The display panel for the semi-transmissive liquid crystal display device according to the present embodiment is then completed by injecting liquid crystal into the gap formed by the TFT active matrix substrate and the opposing substrate and sealing the injection opening.

The semi-transmissive liquid crystal display device completed in this manner has a favorable electrical connection of the interface of the reflective metal film 21b comprised of the third metal conductive film and the transparent conductive film 21a serving as a transmissive pixel electrode film. In addition, the occurrence of display defects attributable to reduction of Indium oxide in the transparent conductive film 21a can be prevented. Consequently, production is possible at a favorable yield with high display quality. In addition, a bilayer film, in which a reflective pixel electrode in the form of Al-based film (Al film or an alloy film having Al as a main component thereof) and having high reflectance and a transmissive electrode in the form of an ITO film having high transmittance are laminated directly, can be composed without having to additionally form a buffer layer. Consequently, production efficiency can be improved.

Furthermore, although an Al—Ni alloy film, in which Ni is added to Al, was used for the third metal conductive film comprising the reflective pixel electrode in the first embodiment, a pure Al film may also be used. Even in the case of using a pure Al film, an interfacial reaction between the Al and the oxygen of the ITO of the lower layer can be inhibited by adding elementary nitrogen. Consequently, electrical connection at the interface with the lower layer transparent conductive film 21a made of ITO is favorable, and reduction of In can be prevented. Although a value of 20 at % was used for the composite ratio of nitrogen in the present embodiment, the composite ratio of nitrogen is not limited thereto. The composite ratio of nitrogen can be arbitrarily set to within a range of 5 to 45 at %. If the composite ratio of nitrogen is less than 5 at %, it is difficult to adequately demonstrate an object of the present invention of preventing reduction of In. In addition, if the composite ratio of nitrogen exceeds 45 at %, the resulting increase in specific resistance makes it difficult to form a conductive film. Moreover, since the reflectance of light having a wavelength of 550 nm falls below 80%, use as a reflective pixel electrode becomes difficult.

Moreover, in this case, similar effects can be obtained even if elementary oxygen is added instead of nitrogen. The interfacial reaction between Al and oxygen of the lower layer ITO can be inhibited by forming a conductive film in which elementary oxygen has been added to Al in advance. As a result, reduction of In can be inhibited. Elementary oxygen can be added by, for example, depositing by sputtering in a mixed gas in which oxygen (O₂) gas has been added to Ar gas. The composite ratio of oxygen can be within the range of 5 to 45 at % in the same manner as in the case of nitrogen. Furthermore, both nitrogen and oxygen can also be added simultaneously.

In addition, an Al—Ni alloy, in which Ni is added to Al, was used for the third metal conductive film comprising the reflective electrode in the embodiment described above. The addition of Ni allows the obtaining of the effect of further improving electrical conductance in the connection with the lower layer transparent conductive film 21a composed of ITO. In addition, the effect of preventing the occurrence of corrosion caused by a battery reaction in the organic alkaline developing solution containing TMAH typically used when patterning a photoresist for etching Al/ITO laminated films can be further enhanced. Although the composite ratio of added Ni was 2 at % in the embodiment described above, the present embodiment is not limited thereto. The effects described above can be further enhanced by increasing the amount of Ni added. However, if the amount of Ni added exceeds 10 at %, the reflectance of the third metal conductive film falls below 80%. Consequently, in the case of applying a thirdmetal conductive film to a reflective pixel electrode as in the present embodiment, the amount of Ni added is preferably 10 at % or less.

Moreover, the added element is not limited to Ni, but rather other elements may also be used. Similar effects can be obtained by adding an element selected from the group consisting of elements of group VIII and elements of group IVb of the periodic table for use as the element added to the third metal conductive film. Among these elements, Ni, Fe, Co, C, Si and Ge are particularly preferable. In addition, one or more types of these elements may also be added in combination. In this case as well, the composite ratio of elements added in total preferably does not exceed 10 at %. Furthermore, after forming a metal film to which has been added an element of group VIII or group IVb of the periodic table as described above as well as nitrogen or oxygen for use as the third metal conductive film, one layer or more layers of an Al film or Al-based alloy film to which other elements have been added may be laminated thereon. In the present embodiment, for example, a film made of Al, 2 at % Ni and 20 at % N is first deposited at a thickness of, for example, 5 to 50 nm by sputtering using a mixed gas of Ar and N₂ on the lower layer transparent conductive film 21a. Next, the gas is switched to pure Ar gas followed by deposition of a film made of Al and 2 at % Ni at a thickness of, for example, 50 to 100 nm by sputtering. As a result thereof, surface reflectance of the reflective pixel electrode and overall electrical conductance can be further enhanced while maintaining the effects of the present invention, which is preferable since it allows the obtaining of high display quality.

In addition, although an ITO film made of indium oxide and tin oxide was used for the transparent conductive film 21a in the first embodiment, the transparent conductive film 21a is not limited thereto. For example, indium oxide alone, indium oxide and zinc oxide (IZO), indium oxide and samarium oxide (ISO), indium oxide, tin oxide and zinc oxide (ITZO), or indium oxide, tin oxide and samarium oxide (ITSO) can also be used. Since these transparent conductive films contain indium oxide, they have high transmittance and high electrical conductance. Thus, these transparent conductive films can be preferably used as electrode films or transmissive pixel electrode films. The effects of the present invention are naturally also able to be adequately obtained even if a transparent conductive film is used that contains an oxide other than indium oxide.

### Second Embodiment

An electro-optical display device according to a second embodiment of the present invention has a TFT active matrix substrate of the same configuration as that used in the semi-transmissive liquid crystal display device of the first embodiment shown in FIGS. 3 and 4. In addition, although the basic process flows of the production method thereof is also the same as that of the first embodiment as shown in FIGS. 5A to 5H, the method of forming the pixel electrode 21 shown in FIG. 5E differs from that of the first embodiment. The following provides a detailed explanation of that difference in the production method.

In the pixel electrode formation step shown in FIG. 5E, the transparent conductive film 21a is first deposited on the second interlayer insulating film 15. Subsequently, plasma comprised mainly of air is irradiated onto the surface of this transparent conductive film 21a. A third metal conductive film is then deposited on the transparent conductive film 21a irradiated with plasma. Subsequently, a photoresist is coated onto the third metal conductive film, and the pattern 24 for forming a pixel electrode, the pattern 25 for forming a gate electrode pad, and the pattern 26 for forming a source terminal pad are at least formed in the fifth photolithography process.

At this time, the film thickness d2 of the photoresist on the opening 19 of the transmissive pixel electrode section is formed to be less than the film thickness d1 of the photoresist of the reflective pixel electrode section. This film thickness d2 is preferably ½ or less the film thickness d1.

In the present embodiment, ITO comprised mainly of indium oxide and tin oxide is deposited at a thickness of 100 nm by a known sputtering method for the transparent conductive film 21a. Subsequently, a treatment gas comprising N₂ gas and O₂ gas is introduced using an atmospheric pressure plasma treatment device, and plasma discharge is allowed to occur by applying about 1.6 kW of radio frequency (RF: 13.566 MHz) electrical power between a pair of electrodes in the vicinity of atmospheric pressure of about 100,000 Pa. The substrate is transported between the electrodes during plasma discharge at a speed of about 1 m/min to treat the surface of the ITO film with plasma. Subsequently, an AlNi alloy target, in which 2 at % (atom %) Ni has been added to Al, is deposited at a thickness of 100 nm by sputtering using Ar gas or Kr gas for the third metal conductive film.

Although surface treatment of the transparent conductive film 21a in the form of an ITO film was carried out by plasma irradiation with N₂ gas and O₂ gas in the vicinity of atmospheric pressure, this surface treatment is not limited thereto, but rather may also be carried out under reduced pressure. The gas flow rates and applied electrical power are also not limited to those described above, but rather can be set arbitrarily according to the specifications of the plasma treatment device used. In addition, an AlNi film containing N atoms or O atoms may also be deposited for the third metal conductive film by using as a target an AlNi alloy, in which 2 at % Ni has been added to Al, and sputtering in a mixed gas in which N₂ gas or O₂ gas has been added to Ar gas or Kr gas. Since the remainder of the process is the same as that of the first embodiment, an explanation thereof is omitted.

### Third Embodiment

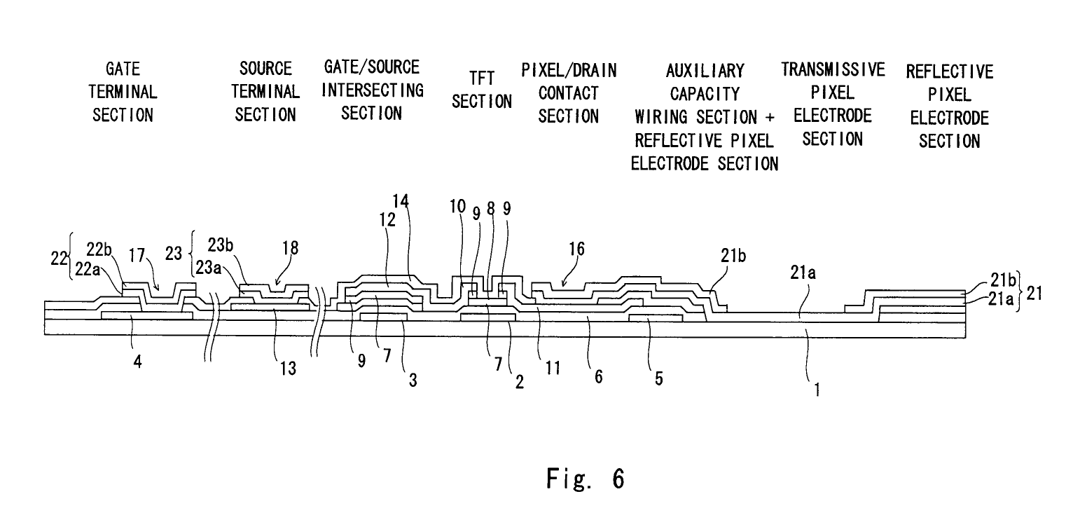

The following provides an explanation of the configuration of a TFT active matrix substrate used in an electro-optical display device according to a third embodiment of the present invention with reference to FIG. 6. FIG. 6 is a cross-sectional view showing the configuration of the TFT active matrix substrate according to the present embodiment. In the present embodiment, the second interlayer insulating film 15 of the first and second embodiments is omitted, and surface irregularities for scattering reflected light are not formed on the reflective pixel electrode. In addition, the production method thereof is able to use the production flow of the first and second embodiments with the exception of omitting the formation of the second interlayer insulating film 15. Thus, the production process can be simplified thereby making it possible to further improve production efficiency.

The optical path lengths of the reflective pixel electrode section and the transmissive pixel electrode section can be aligned by forming step structures corresponding to the path lengths in those regions corresponding to each pixel electrode of an opposing substrate laminated in opposition to the TFT active matrix substrate. In addition, with respect to scattering of reflected light, high display quality can be obtained by providing, for example, an optical film having an effect of scattering light on a semi-transmissive liquid crystal panel in which a TFT active matrix substrate and opposing substrate have been formed by lamination.

Although the above description has provided an explanation of examples of applying the present invention to a pixel electrode of an electro-optical display device, the present invention is not limited thereto. For example, the present invention can also be applied to a laminated film, electrode film or wiring film structure containing a laminated structure comprised of an Al-based metal and ITO in other devices as well.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A laminated conductive film, comprising:
a transparent conductive film having optical transmissivity; and
a metal conductive film laminated directly on the transparent conductive film and electrically connected to the transparent conductive film, wherein
the metal conductive film is made of Al or has Al as a main component thereof, and contains at least one of nitrogen atom and oxygen atom at least in the vicinity of an interface with the transparent conductive film.

2. The laminated conductive film according to claim 1, wherein the metal conductive film further contains at least one type of atom selected from the group consisting of Fe, Co and Ni of group VIII of the periodic table and C, Si and Ge of group IVb of the periodic table in the vicinity of the interface with the transparent conductive film.

3. The laminated conductive film according to claim 1, wherein the transparent conductive film contains indium oxide.

4. The laminated conductive film according to claim 1, wherein the transparent conductive film contains tin oxide.

5. The laminated conductive film according to claim 3, wherein the transparent conductive film contains tin oxide.

6. An electro-optical display device, comprising:
a plurality of gate wiring formed on a substrate;
a plurality of source wiring arranged so as to intersect with the gate wiring with a first insulating film interposed therebetween;
a plurality of thin film transistors formed in the vicinity of intersecting sections of the gate wiring and the source wiring; and
pixel electrodes connected to the thin film transistors and provided in regions surrounded by the gate wiring and the source wiring, wherein
the pixel electrodes are provided with a transmissive region comprising a transparent conductive film, and a reflective region comprising a metal conductive film having Al as a main component thereof, laminated directly on the transparent conductive film and electrically connected to the transparent conductive film, and
the metal conductive film is made of Al or has Al as a main component thereof, and contains at least one of nitrogen atom and oxygen atom at least in the vicinity of an interface with the transparent conductive film.

7. The electro-optical display device according to claim 6, wherein the metal conductive film further contains at least one type of atom selected from the group consisting of Fe, Co and Ni of group VIII of the periodic table and C, Si and Ge of group IVb of the periodic table in the vicinity of the interface with the transparent conductive film.

8. The electro-optical display device according to claim 6, wherein the transparent conductive film contains indium oxide.

9. The electro-optical display device according to claim 6, wherein the transparent conductive film contains tin oxide.

10. The electro-optical display device according to claim 8, wherein the transparent conductive film contains tin oxide.

11. The electro-optical display device according to claim 6, further comprising a second insulating film provided so as to cover the thin film transistors, wherein
the pixel electrodes are formed on the second insulating film, and
the pixel electrodes and the thin film transistors are connected via contact holes provided in the second insulating film.

12. The electro-optical display device according to claim 11, wherein the film thickness of the second insulating film formed corresponding to the reflective region of the pixel electrodes is greater than the film thickness of the second insulating film formed corresponding to the transmissive region of the pixel electrodes.

13. The electro-optical display device according to claim 11, wherein surface irregularities for scattering reflected light are formed on the surface of the second insulating film formed corresponding to the reflective region of the pixel electrodes.

14. A production method of a laminated conductive film, comprising the steps of:
forming a transparent conductive film on a substrate; and
forming a metal conductive film directly on the transparent conductive film, the metal conductive film being made of Al or having Al as a main component thereof and containing at least one of nitrogen atom and oxygen atom at least in the vicinity of an interface with the transparent conductive film.

15. The production method of a laminated conductive film according to claim 14, further comprising the steps of:
depositing the transparent conductive film followed by irradiating the surface thereof with plasma having, as a main component thereof, gas comprising air containing N₂ gas, O₂ gas or both; and
depositing the metal conductive film on the transparent conductive film irradiated with plasma.

16. The production method of a laminated conductive film according to claim 14, wherein the metal conductive film is formed using a metal target made of Al or having Al as a main component thereof, by sputtering using a mixed gas in which a gas containing at least one of nitrogen atom and oxygen atom has been added to Ar or Kr gas.

17. A production method of an electro-optical display device which comprises, on a substrate, a plurality of gate wiring, a plurality of source wiring substantially orthogonal to the gate wiring with a first insulating film interposed therebetween, a plurality of thin film transistors formed in the vicinity of intersecting sections of the gate wiring and the source wiring, and pixel electrodes connected to the thin film transistors and provided in regions surrounded by the gate wiring and the source wiring, the production method comprising the steps of:
forming a transmissive region of the pixel electrodes comprising a transparent conductive film, and
forming a reflective region of the pixel electrodes by laminating, directly on the transparent conductive film, a metal conductive film made of Al or having Al as a main component thereof and containing at least one of nitrogen atom and oxygen atom at least in the vicinity of an interface with the transparent conductive film.

18. The production method of an electro-optical display device according to claim 17, further comprising the step of depositing the transparent conductive film followed by irradiating the surface thereof with plasma having, as a main component thereof, gas comprising air containing N₂ gas, O₂ gas or both.

19. The production method of an electro-optical display device according to claim 17, wherein the metal conductive film is formed using a metal target made of Al or having Al as a main component thereof, by sputtering using a mixed gas in which a gas containing at least one of nitrogen atom and oxygen atom has been added to Ar or Kr gas.

20. The production method of an electro-optical display device according to claim 17, further comprising the steps of:
depositing the metal conductive film followed by forming a photoresist pattern so that the film thickness on the reflective region is greater than the film thickness on the transmissive region;
removing the laminated film of the metal conductive film and the transparent conductive film by etching using the photoresist pattern as a mask;
exposing the surface of the metal conductive film by reducing the film thickness of the photoresist and removing the photoresist on the transmissive region;
exposing the transparent conductive film of the lower layer by selectively removing only the metal conductive film by etching using the photoresist for which the film thickness has been reduced as a mask; and
removing the photoresist for which the overall film thickness has been reduced.
